(19) United States
(12) Patent Application Publication
(10) Pub. No.: US 2026/0247684 A1
(43) Pub. Date: Aug. 20, 2026

(54) SEMICONDUCTOR DEVICE AND METHOD OF MANUFACTURING SEMICONDUCTOR DEVICE

(71) Applicant: Mitsubishi Electric Corporation, Tokyo (JP)

(72) Inventors: Hiroya YAMARIN, Tokyo (JP); Kunitora FUKUI, Tokyo (JP); Kazunori INOUE, Tokyo (JP)

(73) Assignee: Mitsubishi Electric Corporation, Tokyo (JP)

(21) Appl. No.: 19/447,622

(22) Filed: Jan. 13, 2026

(30) Foreign Application Priority Data
Feb. 19, 2025 (JP) 2025-024930

(51) Int. Cl. H10D 64/62; H10D 64/01

(52) U.S. Cl. CPC H10D 64/62; H10D 64/0111

(57) ABSTRACT

A semiconductor device includes a semiconductor substrate having a front surface and a back surface, a front electrode disposed on the front surface of the semiconductor substrate, and a back electrode disposed on the back surface of the semiconductor substrate. The back electrode includes a first electrode and a second electrode. The first electrode is disposed on the second electrode and includes a molybdenum oxide layer including molybdenum oxide. The second electrode includes a nickel layer including nickel. The molybdenum oxide layer is disposed, opposite the semiconductor substrate with respect to the nickel layer, on an outermost layer of the back electrode.

### CROSS REFERENCE TO RELATED APPLICATIONS

This nonprovisional application is based on Japanese Patent Application No. 2025-024930 filed on Feb. 19, 2025 with the Japan Patent Office, the entire contents of which are hereby incorporated by reference.

### BACKGROUND OF THE INVENTION

### Field of the Invention

The present disclosure relates to a semiconductor device and a method of manufacturing a semiconductor device.

### Description of the Background Art

In a semiconductor device described in Japanese Patent Laying-Open No. S57-54364, a molybdenum thin film is provided on a front electrode of a high-frequency transistor.

The semiconductor device described in the above publication is a high-frequency horizontal transistor, and accordingly, the above publication does not describe a back electrode of a semiconductor device. Thus, the above publication does not have any problem associated with providing an excellent electrical joint between a back electrode and solder.

### SUMMARY OF THE INVENTION

The present disclosure has been made in view of the problem described above. An object of the present disclosure is to provide a semiconductor device that can have an excellent electrical joint between a back electrode and solder and a method of manufacturing the same.

A semiconductor device of the present disclosure includes a semiconductor substrate having a front surface and a back surface, a front electrode disposed on the front surface of the semiconductor substrate, and a back electrode disposed on the back surface of the semiconductor substrate. The back electrode includes a first electrode and a second electrode. The first electrode is disposed on the second electrode and includes a molybdenum oxide layer including molybdenum oxide. The second electrode includes a nickel layer including nickel. The molybdenum oxide layer is disposed, opposite the semiconductor substrate with respect to the nickel layer, on an outermost layer of the back electrode.

The semiconductor device of the present disclosure can have an excellent electrical joint between the back electrode and the solder.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic sectional view showing a configuration of a semiconductor device according to Embodiment 1.

FIG. 2 is a flowchart showing a method of manufacturing a semiconductor device according to Embodiment 1.

FIG. 3 is a schematic sectional view showing a configuration of a semiconductor device according to Embodiment 2.

FIG. 4 is a flowchart showing a method of manufacturing a semiconductor device according to Embodiment 2.

FIG. 5 is a schematic sectional view showing a configuration of a semiconductor device according to a modification of Embodiment 2.

FIG. 6 is a schematic sectional view showing a configuration of a semiconductor device according to Embodiment 3.

FIG. 7 is a flowchart showing a method of manufacturing a semiconductor device according to Embodiment 3.

FIG. 8 is a schematic sectional view showing a configuration of a semiconductor device according to Embodiment 4.

FIG. 9 is a flowchart showing a method of manufacturing a semiconductor device according to Embodiment 4.

FIG. 10 is a schematic sectional view showing a configuration of a semiconductor device according to a modification of Embodiment 4.

FIG. 11 is a flowchart showing a method of manufacturing a semiconductor device according to Embodiment 5.

FIG. 12 is a sectional view showing a state during pickup in a chip mounting step of the method of manufacturing a semiconductor device according to Embodiment 5.

FIG. 13 is a sectional view showing an operation of a chip mounter apparatus in the chip mounting step of the method of manufacturing a semiconductor device according to Embodiment 5.

FIG. 14 is a sectional view showing a state in which a molybdenum oxide layer is removed in a cleaning step of the method of manufacturing a semiconductor device according to Embodiment 5.

FIG. 15 is a sectional view showing an operation of a cleaning apparatus in the cleaning step of the method of manufacturing a semiconductor device according to Embodiment 5.

FIG. 16 is a sectional view showing another operation of the cleaning apparatus in the cleaning step of the method of manufacturing a semiconductor device according to Embodiment 5.

FIG. 17 is a sectional view showing a semiconductor device after being cleaned in the cleaning step of the method of manufacturing a semiconductor device according to Embodiment 5.

FIG. 18 is a bottom view of the semiconductor device after being cleaned in the cleaning step of the method of manufacturing a semiconductor device according to embodiment 5.

FIG. 19 is a sectional view showing a die bonding step of the method of manufacturing a semiconductor device according to Embodiment 5.

### DESCRIPTION OF THE PREFERRED EMBODIMENTS

Embodiments will be described below with reference to the drawings. In the following description, the same or corresponding components are denoted by the same reference characters, and redundant description will not be repeated.

### Embodiment 1

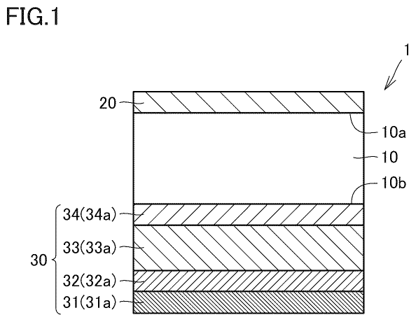

Referring to FIG. 1, a configuration of a semiconductor device 1 according to Embodiment 1 will be described.

As shown in FIG. 1, semiconductor device 1 according to Embodiment 1 includes a semiconductor substrate 10, a front electrode 20, and a back electrode 30. Semiconductor substrate 10 has a front surface 10a and a back surface 10b. Front electrode 20 is disposed on front surface 10a of semiconductor substrate 10. Back electrode 30 is disposed on back surface 10b of semiconductor substrate 10. Back electrode 30 is disposed opposite front electrode 20 with respect to semiconductor substrate 10.

Semiconductor substrate 10 is a Si substrate or a SiC substrate. The layer on the main surface (back surface) side of semiconductor substrate 10, which forms back electrode 30, is an n-type semiconductor layer when semiconductor device 1 is a diode or a metal oxide semiconductor field effect transistor (MOSFET), and is a p-type semiconductor layer when semiconductor device 1 is an insulated gate bipolar transistor (IGBT).

Back electrode 30 includes a plurality of metallic layers. Back electrode 30 includes a first electrode 31 and a second electrode 32. First electrode 31 is disposed on second electrode 32. First electrode 31 includes a molybdenum oxide layer 31a including molybdenum oxide. In the present embodiment, first electrode 31 is molybdenum oxide layer 31a. Second electrode 32 includes a nickel layer 32a including nickel (Ni). In the present embodiment, second electrode 32 is nickel layer 32a. Molybdenum oxide layer 31a is disposed, opposite semiconductor substrate 10 with respect to nickel layer 32a, on the outermost layer of back electrode 30. In the present embodiment, molybdenum oxide layer 31a is electrically conducting. In the present embodiment, a composition x of oxygen (O) contained in the molybdenum oxide (Mo₁₀₀₋ₓOₓ) is preferably 0.1 mol % (mole percent) or more, and more preferably 0.5 mol % or more, to impart water solubility described below. Further, composition x is preferably 75 mol % or less, and more preferably 66.7 mol % or less, to impart conductivity, which will be described later.

In the present embodiment, back electrode 30 includes a third electrode 33 and a fourth electrode 34. In back electrode 30, fourth electrode 34, third electrode 33, second electrode 32, and first electrode 31 are stacked in order from the semiconductor substrate 10 side. Second electrode 32 is disposed on third electrode 33. Third electrode 33 is disposed on fourth electrode 34. Fourth electrode 34 is disposed on back surface 10b of semiconductor substrate 10. Third electrode 33 includes a titanium layer 33a including titanium (Ti) or a titanium alloy. In the present embodiment, third electrode 33 is titanium layer 33a. Fourth electrode 34 includes an aluminum layer 34a including aluminum (Al) or an aluminum alloy. In the present embodiment, fourth electrode 34 is aluminum layer 34a. Titanium layer 33a is disposed on aluminum layer 34a.

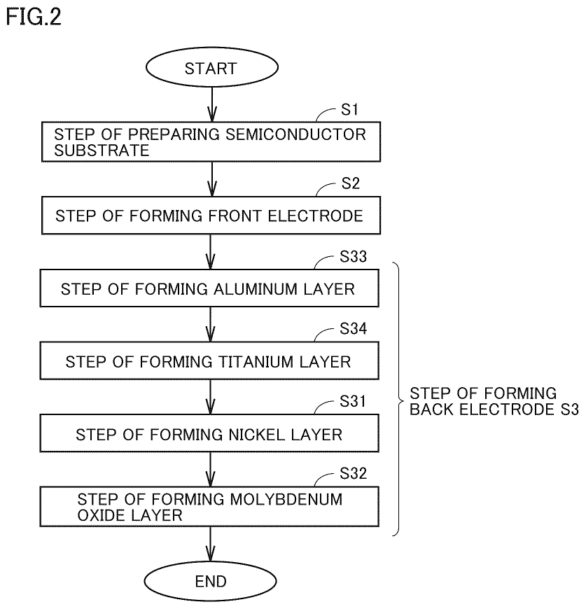

Referring to FIGS. 1 and 2, a method of manufacturing semiconductor device 1 according to Embodiment 1 will be described.

As shown in FIGS. 1 and 2, the method of manufacturing semiconductor device 1 according to Embodiment 1 includes a step S1 of preparing semiconductor substrate 10, a step S2 of forming front electrode 20, and a step S3 of forming back electrode 30.

The step of processing the back surface of semiconductor substrate 10 may be provided between step S2 of forming front electrode 20 and step S3 of forming back electrode 30. For example, the thickness of semiconductor substrate 10 may be reduced, or a p-type semiconductor layer, an n-type semiconductor layer, or any other layer may be partially formed in semiconductor substrate 10.

In step S1 of preparing semiconductor substrate 10, semiconductor substrate 10 having front surface 10a and back surface 10b is prepared. In step S2 of forming front electrode 20, front electrode 20 is formed on front surface 10a of semiconductor substrate 10. In step S3 of forming back electrode 30, back electrode 30 is formed on back surface 10b of semiconductor substrate 10.

Step S3 of forming back electrode 30 includes a step S31 of forming nickel layer 32a including nickel and a step S32 of forming molybdenum oxide layer 31a including molybdenum oxide. Step S32 of forming molybdenum oxide layer 31a is performed subsequent to step S31 of forming nickel layer 32a. Molybdenum oxide layer 31a is formed on the outermost layer of back electrode 30. In the present embodiment, molybdenum oxide layer 31a is formed on nickel layer 32a.

In the present embodiment, step S3 of forming back electrode 30 includes a step S33 of forming aluminum layer 34a including aluminum or an aluminum alloy on back surface 10b of semiconductor substrate 10, and a step S34 of forming titanium layer 33a including titanium or a titanium alloy on aluminum layer 34a. Nickel layer 32a is formed on titanium layer 33a.

In the step of forming back electrode 30, molybdenum oxide layer 31a is formed with a thickness of, for example, 100 nm or less. Molybdenum oxide layer 31a is preferably formed with a thickness of 10 nm or more and 50 nm or less.

In step S3 of forming back electrode 30, molybdenum oxide layer 31a is formed by reactive sputtering using a gas mixture of argon and oxygen as the deposition gas. In reactive sputtering, a molybdenum or molybdenum alloy target is used. The molybdenum alloy target may include nickel (Ni), niobium (Nb), or titanium (Ti).

In step S3 of forming back electrode 30, nickel layer 32a is formed by sputtering using an argon gas as the deposition gas. In sputtering, a nickel or nickel alloy target is used.

Next, functions and effects of Embodiment 1 will be described.

For example, in PTL 2 (Japanese Patent Laying-Open No. H06-77262) and PTL 3 (Japanese Patent Laying-Open No. 2011-233643) as comparative examples, a Au electrode is formed on a surface of a Ni electrode, which has a function of preventing oxidation of the Ni electrode. However, Au has the problem of being very costly (high cost) due to the recent increased demand. In PTL 4 (Japanese Patent Laying-Open No. 2007-63042), a Pd/Au electrode is formed on a surface of a Ni electrode, which has a function of preventing oxidation of the Ni electrode as in the case of forming only the Au electrode. However, though the amount of Au used can be reduced more than when only the Au electrode is used, Au is still consumed, leading to high cost. Further, Pd is still relatively costly though it is less costly than Au.

In semiconductor device 1 according to Embodiment 1, molybdenum oxide layer 31a is disposed, opposite semiconductor substrate 10 with respect to nickel layer 32a, on the outermost layer of back electrode 30. As a result, the formation of nickel oxide on the surface of nickel layer 32a can be suppressed. This can suppress the deterioration of solder wettability during soldering of back electrode 30 due to the formation of the nickel oxide on the surface of nickel layer 32a. Consequently, with back electrode 30 soldered, an excellent electrical joint can be provided between back electrode 30 and the solder. Further, molybdenum oxide, which is water-soluble, does not need to be removed by wet etching using an acidic or alkaline chemical solution. Thus, molybdenum oxide layer 31a can be easily removed, enabling soldering to the surface of nickel layer 32a, where the formation of the nickel oxide is suppressed.

In semiconductor device 1 according to Embodiment 1, third electrode 33 includes titanium layer 33a including titanium or a titanium alloy. Fourth electrode 34 includes aluminum layer 34a including aluminum or an aluminum alloy. Thus, since gold is not used for back electrode 30, the cost of semiconductor device 1 can be reduced more than when gold is used for back electrode 30.

Molybdenum oxide layer 31a, nickel layer 32a, titanium layer 33a, and aluminum layer 34a can be manufactured by the same manufacturing apparatus. This can improve the productivity of semiconductor device 1.

According to the method of manufacturing semiconductor device 1 of Embodiment 1, in step S3 of forming back electrode 30, molybdenum oxide layer 31a is formed on the outermost layer of back electrode 30. Thus, the formation of nickel oxide on the surface of nickel layer 32a can be suppressed. This can suppress deterioration of solder wettability during soldering of back electrode 30 due to the formation of the nickel oxide on the surface of nickel layer 32a. Consequently, with back electrode 30 soldered, an excellent electrical joint can be provided between back electrode 30 and the solder. Further, the molybdenum oxide, which is water-soluble, does not need to be removed by wet etching using an acidic or alkaline chemical solution. Thus, molybdenum oxide layer 31a can be easily removed in a washing step using, for example, pure water. Further, even if molybdenum oxide layer 31a remains, forming molybdenum oxide layer 31a with a thickness of 100 nm or less allows molybdenum oxide layer 31a to be absorbed into the solder, enabling excellent soldering to the surface of nickel layer 32a.

According to the method of manufacturing semiconductor device 1 of Embodiment 1, step S3 of forming back electrode 30 includes step S33 of forming aluminum layer 34a including aluminum or an aluminum alloy on back surface 10b of semiconductor substrate 10, and step S34 of forming titanium layer 33a including titanium or a titanium alloy on aluminum layer 34a. Thus, since gold is not used for back electrode 30, the cost of semiconductor device 1 can be reduced more than when gold is used for back electrode 30. Additionally, molybdenum oxide layer 31a, nickel layer 32a, titanium layer 33a, and aluminum layer 34a can be manufactured by the same manufacturing apparatus. This can improve the productivity of semiconductor device 1.

### Embodiment 2

Embodiment 2 has the same configuration, manufacturing method, and functions and effects as those of Embodiment 1 described above, unless otherwise specified. Therefore, the same components as those of Embodiment 1 described above are denoted by the same reference signs, and description thereof will not be repeated.

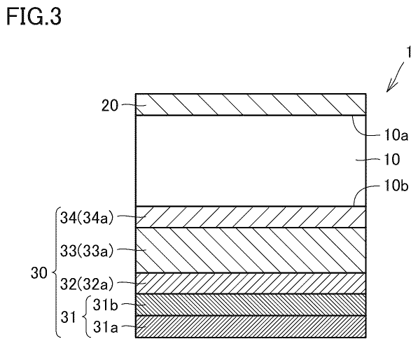

Referring to FIG. 3, the configuration of semiconductor device 1 according to Embodiment 2 will be described.

As shown in FIG. 3, in semiconductor device 1 according to Embodiment 2, first electrode 31 includes a molybdenum layer 31b including molybdenum (Mo). Molybdenum oxide layer 31a is disposed on molybdenum layer 31b. Molybdenum layer 31b is disposed on nickel layer 32a.

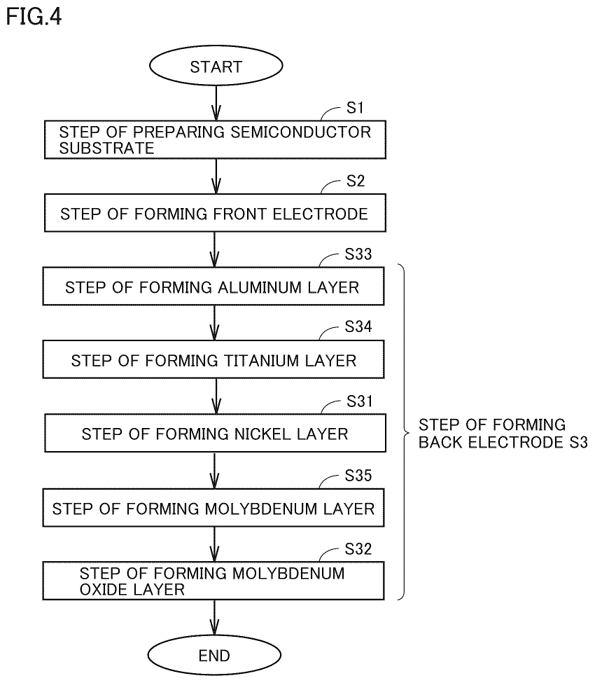

Referring to FIGS. 3 and 4, a method of manufacturing semiconductor device 1 according to Embodiment 2 will be described.

As shown in FIGS. 3 and 4, in the method of manufacturing semiconductor device 1 according to Embodiment 2, step S3 of forming back electrode 30 includes a step S35 of forming molybdenum layer 31b including molybdenum on nickel layer 32a. Step S35 of forming molybdenum layer 31b is performed subsequent to step S31 of forming nickel layer 32a. Step S32 of forming molybdenum oxide layer 31a is performed subsequent to step S35 of forming molybdenum layer 31b. Molybdenum oxide layer 31a is formed on molybdenum layer 31b.

Herein, the thickness of molybdenum layer 31b is preferably 20 nm or more and 500 nm or less. When the thickness of molybdenum layer 31b is smaller than 20 nm, the function of preventing surface oxidation of nickel layer 32a cannot be exhibited sufficiently. When the thickness of molybdenum layer 31b is greater than 500 nm, it is difficult to manufacture semiconductor device 1 at low cost.

In step S3 of forming back electrode 30, molybdenum layer 31b is formed by sputtering using an argon gas as the deposition gas. Molybdenum oxide layer 31a is formed by reactive sputtering using a gas mixture of argon and oxygen as the deposition gas.

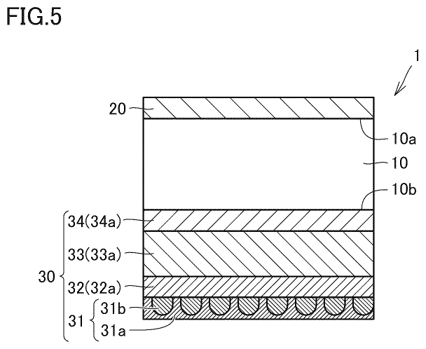

Referring to FIG. 5, the configuration of semiconductor device 1 according to a modification of Embodiment 2 will be described.

As shown in FIG. 5, in semiconductor device 1 according to the modification of Embodiment 2, molybdenum layer 31b is formed in an island shape. Molybdenum oxide layer 31a is formed on the island-shaped molybdenum layer 31b. Molybdenum oxide layer 31a is formed to fill the gaps of the island-shaped molybdenum layer 31b.

Next, functions and effects of Embodiment 2 will be described.

In semiconductor device 1 according to Embodiment 2, molybdenum oxide layer 31a is disposed on molybdenum layer 31b. Molybdenum layer 31b is disposed on nickel layer 32a. Thus, molybdenum layer 31b can suppress the formation of nickel oxide on the surface of nickel layer 32a due to oxygen contained in the reactive sputtering gas during the deposition of molybdenum oxide layer 31a. Consequently, with back electrode 30 soldered, an excellent electrical joint can be provided between back electrode 30 and the solder.

According to the method of manufacturing semiconductor device 1 of Embodiment 2, molybdenum layer 31b is formed on nickel layer 32a in step S3 of forming back electrode 30. Molybdenum oxide layer 31a is formed on molybdenum layer 31b. Thus, molybdenum layer 31b can suppress the formation of nickel oxide on the surface of nickel layer 32a due to oxygen contained in the reactive sputtering gas during the deposition of molybdenum oxide layer 31a. Consequently, with back electrode 30 soldered, an excellent electrical joint can be provided between back electrode 30 and the solder. Further, since molybdenum oxide layer 31a is formed on molybdenum layer 31b, molybdenum oxide layer 31a can be formed easily.

According to the method of manufacturing semiconductor device 1 of Embodiment 2, molybdenum layer 31b is formed by sputtering using a molybdenum or molybdenum alloy target and an argon gas as the deposition gas. Molybdenum oxide layer 31a is formed by reactive sputtering using the same molybdenum or molybdenum alloy target and a gas mixture of argon and oxygen as the deposition gas. As a result, molybdenum layer 31b and molybdenum oxide layer 31a can be deposited at high speed by sputtering and reactive sputtering. This can improve the productivity of semiconductor device 1.

### Embodiment 3

Embodiment 3 has the same configuration, manufacturing method, and functions and effects as those of Embodiment 1 described above, unless otherwise specified. Therefore, the same components as those of Embodiment 1 described above are denoted by the same reference signs, and description thereof will not be repeated.

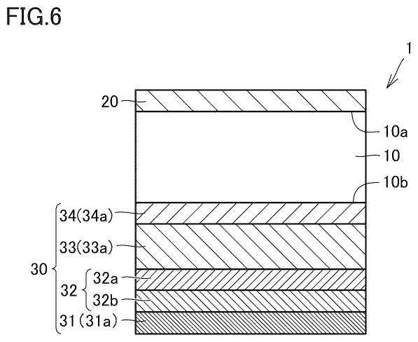

Referring to FIG. 6, the configuration of semiconductor device 1 according to Embodiment 3 will be described.

As shown in FIG. 6, in semiconductor device 1 according to Embodiment 3, second electrode 32 includes nickel nitride layer 32b including nickel nitride. Nickel nitride layer 32b is disposed on nickel layer 32a. Molybdenum oxide layer 31a is disposed on nickel nitride layer 32b. In the present embodiment, a composition y of nitrogen (N) contained in nickel nitride (Ni_{100-y}N_{y}) is preferably 0.1 mol % or more, and more preferably 0.5 mol % or more, to impart an oxidation resistance, which will be described later. Further, composition y is preferably 50 mol % or less, and more preferably 40 mol % or less, to impart conductivity.

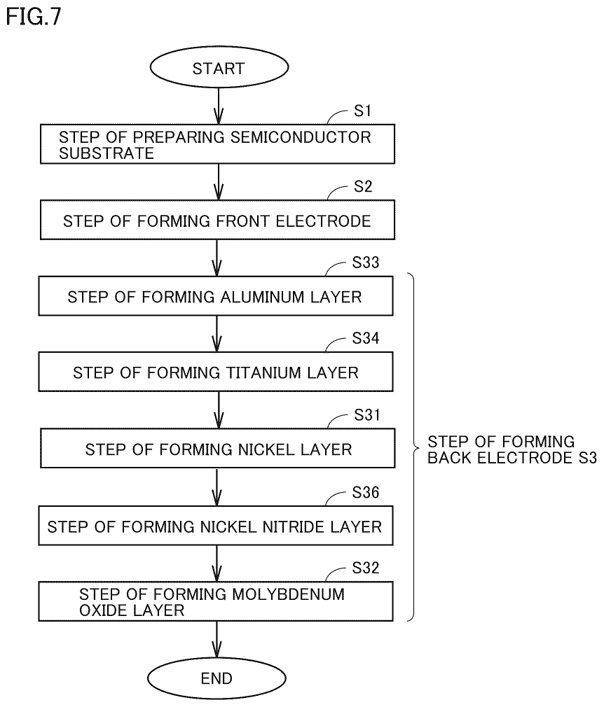

Referring to FIGS. 6 and 7, a method of manufacturing semiconductor device 1 according to Embodiment 3 will be described.

As shown in FIGS. 6 and 7, in the method of manufacturing semiconductor device 1 according to Embodiment 3, step S3 of forming back electrode 30 includes a step S36 of forming nickel nitride layer 32b including nickel nitride on nickel layer 32a. Step S36 of forming nickel nitride layer 32b is performed subsequent to step S31 of forming nickel layer 32a. Step S32 of forming molybdenum oxide layer 31a is performed subsequent to step S36 of forming nickel nitride layer 32b. Molybdenum oxide layer 31a is formed on nickel nitride layer 32b.

In the step of forming back electrode 30, nickel nitride layer 32b is formed with a thickness of, for example, 100 nm or less. Nickel nitride layer 32b is preferably formed with a thickness of 10 nm or more and 30 nm or less.

In step S3 of forming back electrode 30, nickel layer 32a is formed by sputtering using an argon gas as the deposition gas. Nickel nitride layer 32b is formed by reactive sputtering using a gas mixture of argon and nitrogen as the deposition gas. In sputtering and reactive sputtering, a nickel or nickel alloy target is used.

Next, functions and effects of Embodiment 3 will be described.

In semiconductor device 1 according to Embodiment 3, nickel nitride layer 32b is disposed on nickel layer 32a. Thus, nickel nitride layer 32b can suppress the formation of nickel oxide (impart an oxidation resistance) on the surface of nickel layer 32a due to oxygen contained in the reactive sputtering gas during the deposition of molybdenum oxide layer 31a. Consequently, with back electrode 30 soldered, an excellent electrical joint can be provided between back electrode 30 and the solder. Further, nickel nitride layer 32b can improve an oxidation resistance and a resistance to chemical solution, thereby improving the reliability of semiconductor device 1.

According to the method of manufacturing semiconductor device 1 of Embodiment 3, in step S3 of forming back electrode 30, nickel nitride layer 32 b is formed on nickel layer 32a. Molybdenum oxide layer 31a is formed on nickel nitride layer 32b. Thus, nickel nitride layer 32b can suppress the formation of nickel oxide on the surface of nickel layer 32a due to oxygen contained in the reactive sputtering gas during the deposition of molybdenum oxide layer 31a. Consequently, with back electrode 30 soldered, an excellent electrical joint can be provided between back electrode 30 and the solder. Further, since nickel nitride layer 32b is formed on nickel layer 32a, nickel nitride layer 32b can be formed easily.

According to the method of manufacturing semiconductor device 1 of Embodiment 3, nickel layer 32a is formed by sputtering using a nickel or nickel alloy target and an argon gas as the deposition gas. Nickel nitride layer 32b is formed by reactive sputtering using the same nickel or nickel alloy target and a gas mixture of argon and nitrogen as the deposition gas. As a result, nickel layer 32a and nickel nitride layer 32b can be deposited at high speed. This can improve the productivity of semiconductor device 1.

### Embodiment 4

Embodiment 4 has the same configuration, manufacturing method, and functions and effects as those of Embodiments 1 to 3 described above, unless otherwise specified. Therefore, the same components as those of Embodiment 1 described above are denoted by the same reference signs, and description thereof will not be repeated.

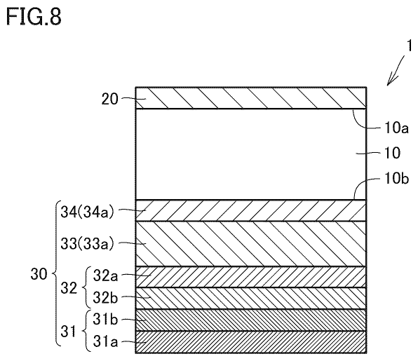

Referring to FIG. 8, the configuration of semiconductor device 1 according to Embodiment 4 will be described.

As shown in FIG. 8, in semiconductor device 1 according to Embodiment 4, first electrode 31 includes molybdenum layer 31b including molybdenum. Molybdenum oxide layer 31a is disposed on molybdenum layer 31b. Second electrode 32 includes nickel nitride layer 32b including nickel nitride. Nickel nitride layer 32b is disposed on nickel layer 32a. Molybdenum layer 31b is disposed on nickel nitride layer 32b. Molybdenum oxide layer 31a is disposed on nickel nitride layer 32b.

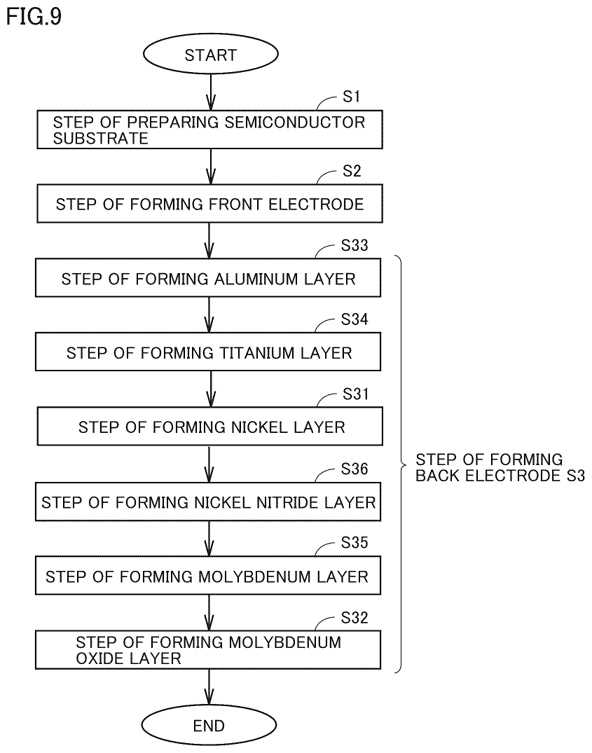

Referring to FIGS. 8 and 9, a method of manufacturing semiconductor device 1 according to Embodiment 4 will be described.

As shown in FIGS. 8 and 9, in the method of manufacturing semiconductor device 1 according to Embodiment 4, step S3 of forming back electrode 30 includes step S36 of forming nickel nitride layer 32b including nickel nitride on nickel layer 32a, and step S35 of forming molybdenum layer 31b including molybdenum on nickel nitride layer 32b. Step S36 of forming nickel nitride layer 32b is performed subsequent to step S31 of forming nickel layer 32a. Step S35 of forming molybdenum layer 31b is performed subsequent to step S36 of forming nickel nitride layer 32b. Step S32 of forming molybdenum oxide layer 31a is performed subsequent to step S35 of forming molybdenum layer 31b. Molybdenum oxide layer 31a is formed on molybdenum layer 31b. Molybdenum layer 31b is disposed on nickel nitride layer 32b.

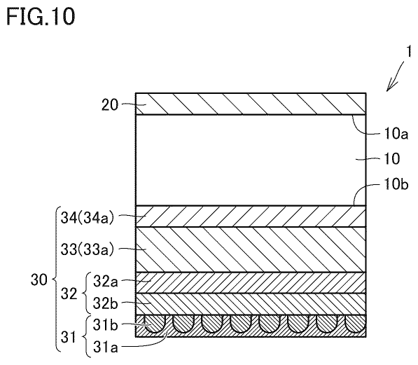

Referring to FIG. 10, the configuration of semiconductor device 1 according to a modification of Embodiment 4 will be described.

As shown in FIG. 10, in semiconductor device 1 according to the modification of Embodiment 4, molybdenum layer 31b is formed in an island shape. Molybdenum oxide layer 31a is formed on the island-shaped molybdenum layer 31b. Molybdenum oxide layer 31a is formed to fill the gaps of island-shaped molybdenum layer 31b.

Next, functions and effects of embodiment 4 will be described.

In semiconductor device 1 according to Embodiment 4, molybdenum oxide layer 31a is disposed on molybdenum layer 31b. Nickel nitride layer 32b is disposed on nickel layer 32a. Molybdenum layer 31b is disposed on nickel nitride layer 32b. Thus, molybdenum layer 31b and nickel nitride layer 32b can suppress the formation of nickel oxide on the surface of nickel layer 32a due to oxygen contained in the reactive sputtering gas during the deposition of molybdenum oxide layer 31a. Consequently, with back electrode 30 soldered, an excellent electrical joint can be provided between back electrode 30 and the solder.

According to the method of manufacturing semiconductor device 1 of Embodiment 4, in the step of forming back electrode 30, nickel nitride layer 32 b is formed on nickel layer 32a. Molybdenum layer 31b is formed on nickel nitride layer 32b. Molybdenum oxide layer 31a is formed on molybdenum layer 31b. Thus, molybdenum layer 31b and nickel nitride layer 32b can suppress the formation of nickel oxide on the surface of nickel layer 32a due to oxygen contained in the reactive sputtering gas during the deposition of molybdenum oxide layer 31a. Consequently, with back electrode 30 soldered, an excellent electrical joint can be provided between back electrode 30 and the solder. Further, since molybdenum oxide layer 31a is formed on molybdenum layer 31b, molybdenum oxide layer 31a can be formed easily.

### Embodiment 5

Embodiment 5 has the same configuration, manufacturing method, and functions and effects as those of Embodiment 1 described above, unless otherwise specified. Therefore, the same components as those of Embodiment 1 described above are denoted by the same reference signs, and description thereof will not be repeated.

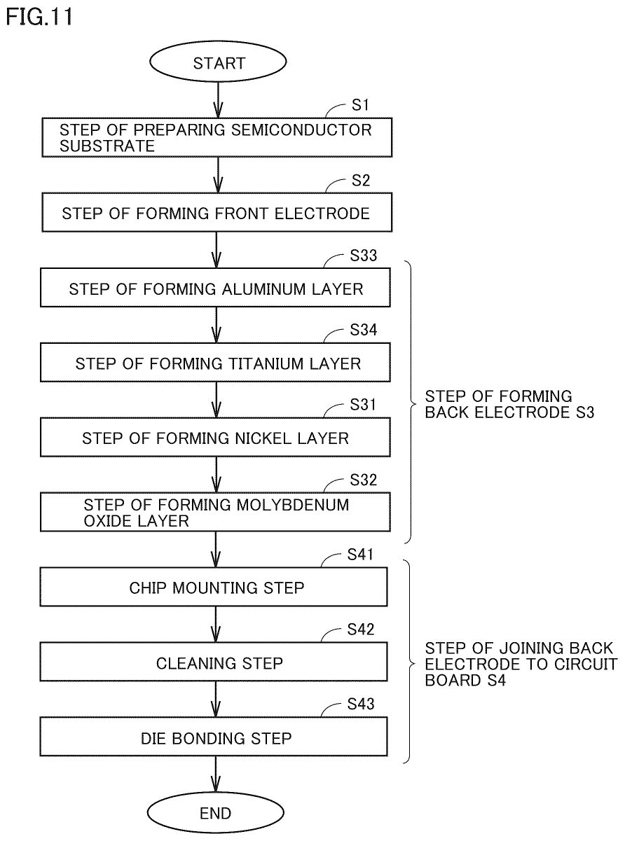

Referring to FIGS. 11 to 19, a method of manufacturing semiconductor device 1 according to Embodiment 5 will be described.

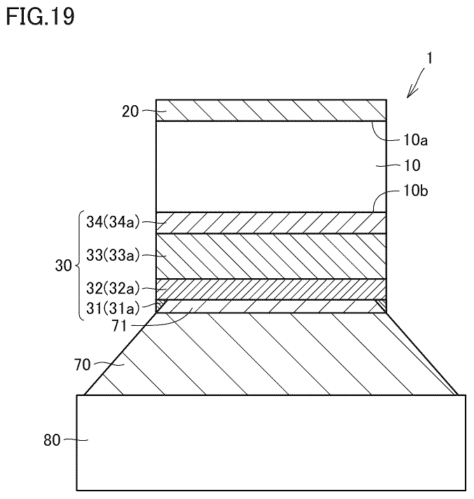

As shown in FIGS. 11 and 19, the method of manufacturing semiconductor device 1 according to Embodiment 4 further includes a step S4 of joining back electrode 30 to circuit board 80. Step S4 of joining back electrode 30 to circuit board 80 is performed subsequent to step S3 of forming back electrode 30.

As shown in FIG. 11, a dicing step is performed between step S32 of forming molybdenum oxide layer 31a and a chip mounting step S41, and a wafer is processed into chips by dicing.

In step S4 of joining back electrode 30 to circuit board 80, back electrode 30 is joined to circuit board 80 with solder 70 in between. Step S4 of joining back electrode 30 to circuit board 80 includes chip mounting step S41, a cleaning step S42, and a die bonding step S43. Cleaning step S42 is performed subsequent to chip mounting step S41. Die bonding step S43 is performed subsequent to cleaning step S42.

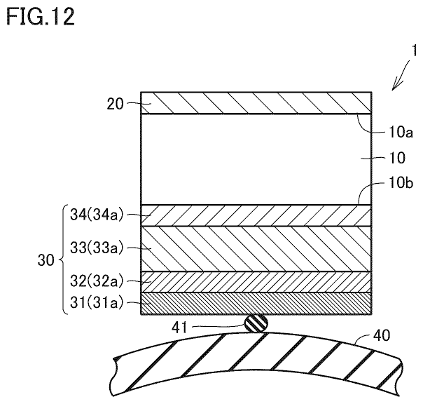

As shown in FIG. 12, in the method of manufacturing semiconductor device 1 according to Embodiment 5, in chip mounting step S41 of step S4 of joining back electrode 30 to circuit board 80, semiconductor device 1 is picked up. When an adhesive residue 41 of a dicing tape 40 occurs during pickup, a failure of joining between back electrode 30 and the solder occurs.

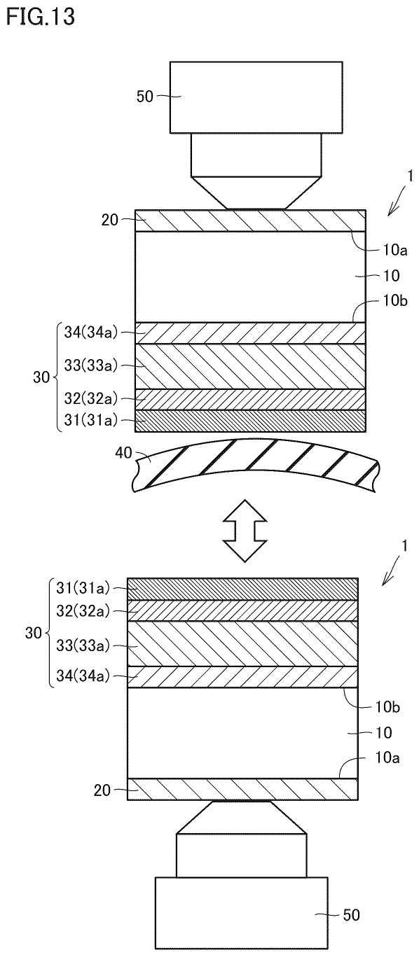

As shown in FIG. 13, in chip mounting step S41 of step S4 of joining back electrode 30 to circuit board 80, chip mounter apparatus 50 has a mechanism that can rotate semiconductor device 1 by 180° while holding semiconductor device 1. Chip mounter apparatus 50 is configured to transport semiconductor device 1 to the next step while holding semiconductor device 1.

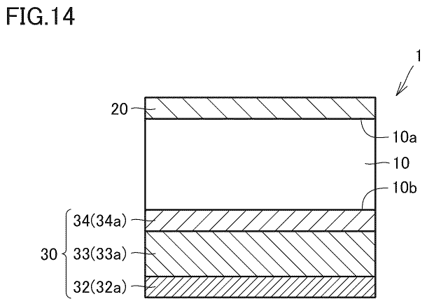

As shown in FIGS. 14 to 16, in the method of manufacturing semiconductor device 1 according to Embodiment 5, in cleaning step S42 of step S4 of joining back electrode 30 to circuit board 80, at least part of molybdenum oxide layer 31a of back electrode 30 is removed. As shown in FIG. 14, molybdenum oxide layer 31a may be entirely removed.

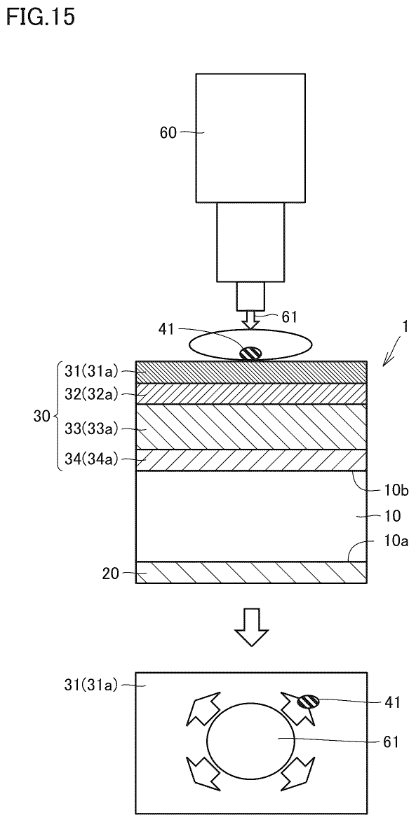

As shown in FIG. 15, molybdenum oxide layer 31a is removed by a cleaning solution 61 supplied from a cleaning apparatus 60. Cleaning apparatus 60 has a transport mechanism that can continuously clean semiconductor device 1 while holding semiconductor device 1. Cleaning apparatus 60 includes a water supply mechanism that supplies cleaning solution 61 and a drainage mechanism that discharges cleaning solution 61. Cleaning apparatus 60 further includes a drying mechanism involving nitrogen blowing, warm air, and spin rotation.

Cleaning solution 61 is a water-soluble cleaning solution. The hydrogen ion index of the water-soluble cleaning solution is preferably pH 4 or more and pH 6 or less. The water-soluble cleaning solution is, for example, pure water, water-soluble flux, or reduced water (hydrogen water). With back electrode 30 disposed on the upper side, cleaning solution 61 may be supplied to the upper surface of molybdenum oxide layer 31a of back electrode 30 to remove molybdenum oxide layer 31a.

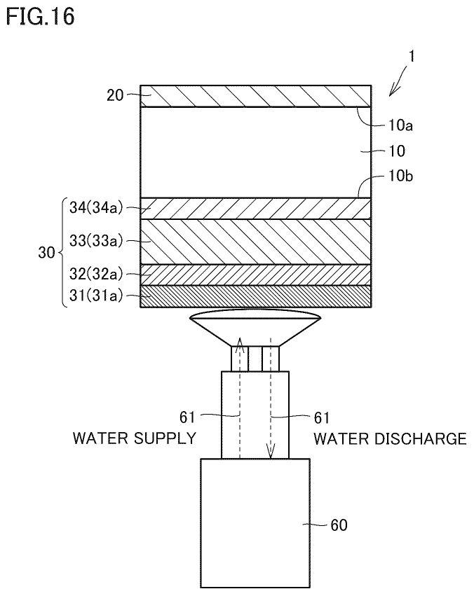

As shown in FIG. 16, with back electrode 30 disposed on the lower side, cleaning solution 61 may be supplied to the lower surface of molybdenum oxide layer 31a of back electrode 30 to remove molybdenum oxide layer 31a. Cleaning solution 61 flows upward in cleaning apparatus 60 and is supplied to back electrode 30, and after cleaning, flows downward in cleaning apparatus 60 to be discharged.

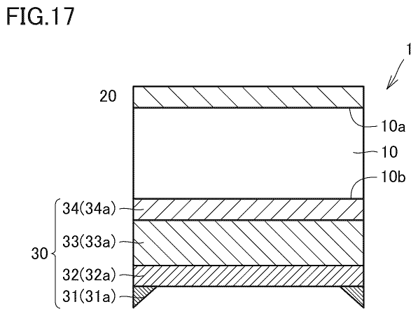

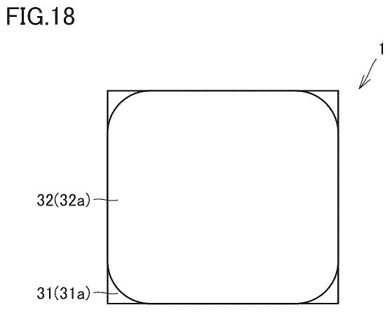

As shown in FIGS. 17 and 18, part of molybdenum oxide layer 31a may remain. Molybdenum oxide layer 31a may remain on the outer periphery of back electrode 30. Molybdenum oxide layer 31a may remain at four corners of back electrode 30.

As shown in FIG. 19, in the method of manufacturing semiconductor device 1 according to Embodiment 5, in die bonding step S43 of step S4 of joining back electrode 30 to circuit board 80, back electrode 30 is joined to circuit board 80 with solder 70 in between with at least part of molybdenum oxide layer 31a of back electrode 30 removed in cleaning step S42. A nickel-solder mixed layer 71 is formed between nickel layer 32a and solder 70.

Semiconductor device 1 manufactured as described above is, for example, wired to a module of case type or mold type and is sealed with resin, thereby forming a power module.

Next, functions and effects of Embodiment 5 will be described.

According to the method of manufacturing semiconductor device 1 of Embodiment 5, back electrode 30 is joined to circuit board 80 with solder 70 in between. Thus, semiconductor device 1 in which back electrode 30 is joined to circuit board 80 with solder 70 in between can be provided.

According to the method of manufacturing semiconductor device 1 of Embodiment 5, back electrode 30 is joined to circuit board 80 with solder 70 in between with at least part of molybdenum oxide layer 31a of back electrode 30 removed in cleaning step S42. As a result, even if adhesive residue 41 of dicing tape 40 occurs during pickup, adhesive residue 41 can be removed together with molybdenum oxide layer 31a. This can suppress the occurrence of a failure of joining between back electrode 30 and the solder. Consequently, with back electrode 30 soldered, an excellent electrical joint can be provided between back electrode 30 and the solder.

The method of manufacturing semiconductor device 1 according to Embodiment 5 can prevent solder 70 from creeping up the side surface of semiconductor device 1 by leaving part of molybdenum oxide layer 31a. In addition, the thickness of solder 70 can be made uniform easily.

The embodiments described above can be combined as appropriate.

The embodiments disclosed herein should be considered to be illustrative and non-restrictive in every respect. It is intended that the scope of the present disclosure is defined by claims, not only by the above description, and encompasses all modifications and variations equivalent in meaning and scope to the claims.

The embodiments of the present disclosure will be summarized below as additional notes.

### Additional Note 1

A semiconductor device including:
a semiconductor substrate having a front surface and a back surface;
a front electrode disposed on the front surface of the semiconductor substrate; and
a back electrode disposed on the back surface of the semiconductor substrate, wherein
the back electrode includes a first electrode and a second electrode,
the first electrode is disposed on the second electrode and includes a molybdenum oxide layer including molybdenum oxide,
the second electrode includes a nickel layer including nickel, and
the molybdenum oxide layer is disposed, opposite the semiconductor substrate with respect to the nickel layer, on an outermost layer of the back electrode.

### Additional Note 2

The semiconductor device according to additional note 1, wherein
the back electrode includes a third electrode and a fourth electrode,
the second electrode is disposed on the third electrode,
the third electrode is disposed on the fourth electrode,
the third electrode includes a titanium layer including titanium or a titanium alloy,
the fourth electrode includes an aluminum layer including aluminum or an aluminum alloy, and
the titanium layer is disposed on the aluminum layer.

### Additional Note 3

The semiconductor device according to additional note 1 or 2, wherein
the first electrode includes a molybdenum layer including molybdenum,
the molybdenum oxide layer is disposed on the molybdenum layer, and
the molybdenum layer is disposed on the nickel layer.

### Additional Note 4

The semiconductor device according to additional note 1 or 2, wherein
the second electrode includes a nickel nitride layer including nickel nitride, and
the nickel nitride layer is disposed on the nickel layer.

### Additional Note 5

The semiconductor device according to additional note 1, wherein
the first electrode includes a molybdenum layer including molybdenum,
the molybdenum oxide layer is disposed on the molybdenum layer,
the second electrode includes a nickel nitride layer including nickel nitride,
the nickel nitride layer is disposed on the nickel layer, and
the molybdenum layer is disposed on the nickel nitride layer.

### Additional Note 6

A method of manufacturing a semiconductor device, the method including:
preparing a semiconductor substrate having a front surface and a back surface;
forming a front electrode on the front surface of the semiconductor substrate; and
forming a back electrode on the back surface of the semiconductor substrate, wherein
the forming of the back electrode includes
   forming a nickel layer including nickel, and
   forming a molybdenum oxide layer including molybdenum oxide, and
the molybdenum oxide layer is formed on an outermost layer of the back electrode.

### Additional Note 7

The method of manufacturing a semiconductor device according to additional note 6, wherein
the forming of the back electrode includes
   forming an aluminum layer including aluminum or an aluminum alloy on the back surface of the semiconductor substrate, and
   forming a titanium layer including titanium or a titanium alloy on the aluminum layer, and
the nickel layer is formed on the titanium layer.

### Additional Note 8

The method of manufacturing a semiconductor device according to additional note 6 or 7, wherein
the forming of the back electrode includes forming a molybdenum layer including molybdenum on the nickel layer, and
the molybdenum oxide layer is formed on the molybdenum layer.

### Additional Note 9

The method of manufacturing a semiconductor device according to additional note 8, wherein
in the forming of the back electrode, the molybdenum layer is formed by reactive sputtering using an argon gas as a deposition gas, and
the molybdenum oxide layer is formed by reactive sputtering using a gas mixture of argon and oxygen as the deposition gas.

### Additional Note 10

The method of manufacturing a semiconductor device according to additional note 6 or 7, wherein
the forming of the back electrode includes forming a nickel nitride layer including nickel nitride on the nickel layer, and
the molybdenum oxide layer is formed on the nickel nitride layer.

### Additional Note 11

The method of manufacturing a semiconductor device according to additional note 10, wherein
in the forming of the back electrode, the nickel layer is formed by reactive sputtering using an argon gas as a deposition gas, and
the nickel nitride layer is formed by reactive sputtering using a gas mixture of argon and nitrogen as the deposition gas.

### Additional Note 12

The method of manufacturing a semiconductor device according to additional note 6, wherein
the forming of the back electrode includes
   forming a nickel nitride layer including nickel nitride on the nickel layer, and
   forming a molybdenum layer including molybdenum on the nickel nitride layer, and
the molybdenum oxide layer is formed on the molybdenum layer.

### Additional Note 13

The method of manufacturing a semiconductor device according to any one of additional notes 6 to 12, further including joining the back electrode to a circuit board with solder in between.

### Additional Note 14

The method of manufacturing a semiconductor device according to additional note 13, wherein
the joining of the back electrode to the circuit board includes a cleaning step of removing at least part of the molybdenum oxide layer of the back electrode, and
with the at least part of the molybdenum oxide layer of the back electrode removed in the cleaning step, the back electrode is joined to the circuit board with the solder in between.

Although the embodiments of the present invention have been described, it should be understood that the embodiments disclosed herein are illustrative and non-restrictive in every respect. The scope of the present invention is defined by the terms of the claims and is intended to include any modifications within the scope and meaning equivalent to the terms of the claims.

What is claimed is:

1. A semiconductor device comprising:
a semiconductor substrate having a front surface and a back surface;
a front electrode disposed on the front surface of the semiconductor substrate; and
a back electrode disposed on the back surface of the semiconductor substrate, wherein
the back electrode includes a first electrode and a second electrode,
the first electrode is disposed on the second electrode and includes a molybdenum oxide layer including molybdenum oxide,
the second electrode includes a nickel layer including nickel, and
the molybdenum oxide layer is disposed, opposite the semiconductor substrate with respect to the nickel layer, on an outermost layer of the back electrode.

2. The semiconductor device according to claim 1, wherein
the back electrode includes a third electrode and a fourth electrode,
the second electrode is disposed on the third electrode,
the third electrode is disposed on the fourth electrode,
the third electrode includes a titanium layer including titanium or a titanium alloy,
the fourth electrode includes an aluminum layer including aluminum or an aluminum alloy, and
the titanium layer is disposed on the aluminum layer.

3. The semiconductor device according to claim 1, wherein
the first electrode includes a molybdenum layer including molybdenum,
the molybdenum oxide layer is disposed on the molybdenum layer, and
the molybdenum layer is disposed on the nickel layer.

4. The semiconductor device according to claim 1, wherein
the second electrode includes a nickel nitride layer including nickel nitride, and
the nickel nitride layer is disposed on the nickel layer.

5. The semiconductor device according to claim 1, wherein
the first electrode includes a molybdenum layer including molybdenum,
the molybdenum oxide layer is disposed on the molybdenum layer,
the second electrode includes a nickel nitride layer including nickel nitride,
the nickel nitride layer is disposed on the nickel layer, and
the molybdenum layer is disposed on the nickel nitride layer.

6. A method of manufacturing a semiconductor device, the method comprising:
preparing a semiconductor substrate having a front surface and a back surface;
forming a front electrode on the front surface of the semiconductor substrate; and
forming a back electrode on the back surface of the semiconductor substrate, wherein
the forming of the back electrode includes
forming a nickel layer including nickel, and
forming a molybdenum oxide layer including molybdenum oxide, and
the molybdenum oxide layer is formed on an outermost layer of the back electrode.

7. The method of manufacturing a semiconductor device according to claim 6, wherein
the forming of the back electrode includes
forming an aluminum layer including aluminum or an aluminum alloy on the back surface of the semiconductor substrate, and
forming a titanium layer including titanium or a titanium alloy on the aluminum layer, and
the nickel layer is formed on the titanium layer.

8. The method of manufacturing a semiconductor device according to claim 6, wherein
the forming of the back electrode includes forming a molybdenum layer including molybdenum on the nickel layer, and
the molybdenum oxide layer is formed on the molybdenum layer.

9. The method of manufacturing a semiconductor device according to claim 8, wherein
in the forming of the back electrode, the molybdenum layer is formed by reactive sputtering using an argon gas as a deposition gas, and
the molybdenum oxide layer is formed by reactive sputtering using a gas mixture of argon and oxygen as the deposition gas.

10. The method of manufacturing a semiconductor device according to claim 6, wherein
the forming of the back electrode includes forming a nickel nitride layer including nickel nitride on the nickel layer, and
the molybdenum oxide layer is formed on the nickel nitride layer.

11. The method of manufacturing a semiconductor device according to claim 10, wherein
in the forming of the back electrode, the nickel layer is formed by reactive sputtering using an argon gas as a deposition gas, and
the nickel nitride layer is formed by reactive sputtering using a gas mixture of argon and nitrogen as the deposition gas.

12. The method of manufacturing a semiconductor device according to claim 6, wherein
the forming of the back electrode includes
forming a nickel nitride layer including nickel nitride on the nickel layer, and
forming a molybdenum layer including molybdenum on the nickel nitride layer, and
the molybdenum oxide layer is formed on the molybdenum layer.

13. The method of manufacturing a semiconductor device according to claim 6, further comprising joining the back electrode to a circuit board with solder in between.

14. The method of manufacturing a semiconductor device according to claim 13, wherein
the joining of the back electrode to the circuit board includes a cleaning step of removing at least part of the molybdenum oxide layer of the back electrode, and
with the at least part of the molybdenum oxide layer of the back electrode removed in the cleaning step, the back electrode is joined to the circuit board with the solder in between.
